(19) United States
(12) Patent Application Publication
(10) Pub. No.: US 2011/0148670 A1
(43) Pub. Date: Jun. 23, 2011

(54) PORTABLE CHARACTER INPUT APPARATUS AND METHOD USING CHANGE IN TENSION OF STRINGS CONNECTED TO FINGERS

(75) Inventors: Jae-Cheol SIM, Daejeon-si (KR); Kee-Seong Cho, Daejeon-si (KR)

(73) Assignee: Electronics and Telecommunications Research Institute, Daejeon-si (KR)

(21) Appl. No.: 12/965,524

(22) Filed: Dec. 10, 2010

(30) Foreign Application Priority Data
Dec. 21, 2009 (KR) 10-2009-0128026

(51) Int. Cl. H03M 11/00

(52) U.S. Cl. 341/22

(57) ABSTRACT

A portable character input apparatus which is compact and uses strings connected to each finger to input characters. The portable character input apparatus includes a plurality of wearing units, each configured to be worn on or attached to a finger; at least one or more first connection strings, each configured to be attached to the wearing units; a detecting unit configured to detect a change of tension on the first connecting string according to movement of the finger wearing the wearing unit; and a tension change analysis unit configured to analyze the change of tension detected by the detection unit to determine position of an input key that corresponds to the movement of the finger. Accordingly, a keyboard row is determined based on a change of tension related to a user's finger movement, and then position of an input key belonging to the keyboard row can be obtained.

### CROSS-REFERENCE TO RELATED APPLICATION(S)

This application claims the benefit under 35 U.S.C. §119(a) of Korean Patent Application No. 10-2009-0128026, filed on Dec. 21, 2009, in the Korean Intellectual Property Office, the entire disclosure of which is incorporated herein by reference for all purposes.

### BACKGROUND

1. Field

The following description relates to a portable character input apparatus, and more particularly, to a compact character input apparatus which is easy to carry and can input characters based on changes of tension on strings connected to user's fingers.

2. Description of the Related Art

With the wide distribution of information electronic appliances, information input means have been increasingly diversified, including a keyboard, a mouse, a touch screen, a track ball, and the like. In particular, for a handheld information electronic appliance, a touch screen is widely used since it is regarded as an intuitive and effective input means. However, the touch screen is less efficient than a keyboard in terms of inputting characters. That is, the touch screen provides a virtual keyboard including input keys which are graphically displayed for receiving text inputs such as characters, and detects finger touch on a region of the input key. However, as information electronic appliances such as a mobile terminal including a mobile phone and a personal digital assistant (PDA) become more compact, a smaller touch screen region is provided, and thus it is more difficult to use a virtual keyboard. In addition, since a user holds a portable terminal in one or both hands, the data input may be performed inaccurately.

To overcome the above drawbacks, a detachable keyboard has been introduced. The detachable keyboard can provide an input device of the same size as that of a general keyboard, so that data input can be performed easily and accurately. However, the detachable keyboard is not widely used since a user needs to endure the inconvenience of carrying the keyboard all the time for use.

As another method of overcoming the above drawbacks, a motion sensing keyboard has been developed, which operates by detecting finger gestures of a user through a glove or a camera. Like the detachable keyboard, the glove for detecting movements of user's finger joints always needs to be carried by the user, and even worse, the glove is large in volume and accordingly it is not easy to carry in a pocket. The camera that detects movements of user's fingers has limitation in usage environment since it uses the camera images, and for example, the camera cannot detect accurately the finger movement in a dim environment. In addition, the implementation of camera based motion sensing requires complicated procedures.

### SUMMARY

The following description relates to a portable character input apparatus which provides character input efficiency at the same level as a general keyboard to a user without requiring additional effort of becoming accustomed to the portable character input apparatus.

In one general aspect, provided is a portable character input apparatus including: a plurality of wearing units, each configured to be worn on or attached to a finger; at least one or more first connection strings, each configured to be attached to the wearing units; a detecting unit configured to detect a change of tension on the first connecting string according to movement of the finger wearing the wearing unit; and a tension change analysis unit configured to analyze the change of tension detected by the detection unit to acquire position information of an input key that corresponds to the movement of the finger.

The detecting unit may be further configured to include a second connection string configured to be formed of elastic material and connected to the first connection string and a sensor unit configured to detect the change of tension on the first connection string through the second connection string and convert the detected change of tension into an electrical signal.

Among the plurality of wearing units, a wearing unit worn on the thumb may be configured to be connected to a single first connection string, and each of the rest of the wearing units may be connected to a wearing unit adjacent to the detection unit by two first connection strings crossing each other in an X shape.

The portable character input apparatus may further include a tension measurement information storage unit configured to store threshold values for keyboard rows of a keyboard which are set according to each user based on a change of tension occurring upon key input from each user, and a tension change information table with respect to changes of tension on the first connection string according to movements of the fingers excluding the thumb.

The tension change analysis unit may be further configured to include a keyboard row determination unit configured to, in response to receiving tension change information converted into an electrical signal from the sensor unit, compare a value of the received electrical signal and the threshold values for identifying the keyboard rows which are stored in the tension measurement information storage unit to determine a keyboard row related to the received tension change information, and a key position information acquisition unit configured to acquire position information of an input key belonging to the keyboard row determined by the key determination unit with reference to the tension change information table stored in the tension measurement information storage unit.

The tension measurement information storage unit may be configured to store standard threshold values for the respective keyboard rows, and the keyboard row determination unit is further configured to determine a keyboard row using the standard threshold values when the threshold values for the respective keyboard rows which are set according to each user are not stored in the tension measurement information storage unit.

Other features and aspects may be apparent from the following detailed description, the drawings, and the claims.

### BRIEF DESCRIPTION OF THE DRAWINGS

FIG. 1 is a diagram illustrating an example of a portable character input apparatus.

FIG. 2 is a diagram illustrating an example of a change of tension according to upward movement of a right little finger.

FIG. 3 is a diagram illustrating an example of a change of tension according to a horizontal movement of a right little finger.

FIG. 4 is a diagram illustrating an example of a change of tension according to upward movement of a right ring finger.

FIG. 5 is a flowchart illustrating an example of a method of determining position of an input key.

FIG. 6 is a flowchart illustrating an example of a method of determining a keyboard row related to tension change information.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

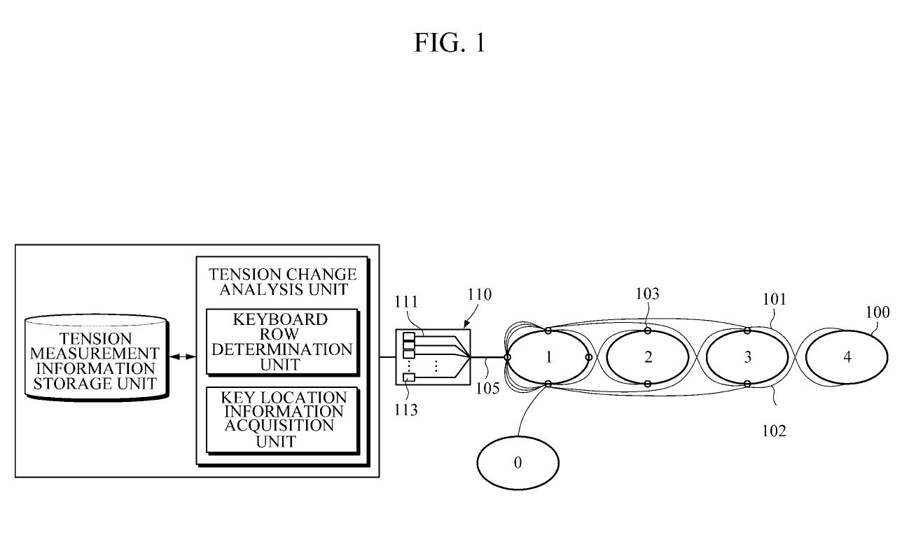

FIG. 1 illustrates an example of a portable character input apparatus.

The portable character input apparatus is assumed to be operated in the same way in the right and the left hands, and thus in the example illustrated in FIG. 1, a portable character input apparatus for right-handed users will be described.

As shown in the example illustrated in FIG. 1, the portable character input apparatus may include a plurality of wearing units 0, 1, 2, 3, and 4, and at most two first connection strings 101 and 102 for each wearing unit, a detection unit 110, a tension change analysis unit 120, and a tension measurement information storage unit 125.

The respective wearing units 0, 1, 2, 3, and 4 which are worn on fingers of a user may be ring- or thimble-shaped, and formed of elastic material such as rubber, so that they can be prevented from easily falling off of the fingers. The wearing units 0, 1, 2, 3, and 4 are designed to correspond to the respective fingers, and each includes a fixation unit 103 to attach the first connection strings 101 and 102 thereto.

The first connection strings 101 and 102 pass through the respective fixation units 103 to connect the wearing units 0, 1, 2, 3, and 4. In the example, the wearing unit 0 to be worn on the thumb is connected to one first connection string 102. The rest of the wearing units 1 through 4 are connected to the two first connection strings 101 and 102 each. As such, the two connection strings 101 and 102 may cross each other in an X shape in a direction of the detection unit 110 which will be described later. For example, the wearing unit 2 to be worn on a middle finger is connected to the neighboring wearing unit 1 adjacent to the detection unit 110 by the two first connection strings 101 and 102 crossing each other in an X shape. In other words, the first connection string 102 to be connected to the wearing unit 0 to be worn on the thumb is connected to the detection unit 110 via the fixation unit 103 of the wearing unit 1. In addition, the first connection strings 101 and 102 for each wearing units 1 through 4 to be connected to one of the wearing units 1 through 4 excluding the wearing unit 0 to be worn on the thumb connect the wearing units 1 through 4, while crossing in an X shape in a direction of the detection unit 110, and are connected to the detection unit 110 via the fixation unit 103 of the wearing unit 1. In this case, the first connection strings 101 and 102 may be designed to have an appropriate length that allows each wearing units 0 through 4 to be placed at a distance similar to a distance between keys on a keyboard. Here, the keyboard may be a general keyboard such as a QWERTY keyboard. Moreover, all of the first connection strings 101 and 102 to be connected to the wearing units 0 through 4 may be inserted into a string guide unit 105 and connected to the detection unit 110.

The detection unit 110 may detect tension on each of the first connection strings 101 and 102 inserted into the string guide unit 105 based on the movement of the fingers wearing the respective wearing units 0 through 4. The detection unit 110 may detect a change of tension on each of the first connection strings 101 and 102 using second connection strings 111 and a sensor unit 113. The second connection strings 111 may be formed of an elastic material such as rubber, and connected to the first connection strings 101 and 102 inserted into the string guide unit 105. In the example illustrated in FIG. 1, the first connection strings 101 and 102 connected to the wearing units 0 through 4 are formed of nine connection strings, and the second connection strings 111 are nine strings, which are connected to the respective first connection strings 101 and 102 one by one.

The sensor unit 113 detects a change of tension on each of the first connection strings 101 and 102 through the second connection strings 111, and converts the detected tension into a digital tension value by A/D conversion. In the example, the sensor unit 130 may be implemented as a piezoelectric sensor. A piezoelectric sensor is a sensor that outputs various voltages according to the magnitude of an applied force, and in the example illustrated in FIG. 1, the sensor unit 113 detects a change of tension on the first connection strings 101 and 102 and converts the detected tension into a digital tension value which varies according to the amount of change. There may be nine sensor units 113, and the sensor units 113 are connected to the respective second connection strings 111 to detect the change of tension on the first connection strings 101 and 102 and convert the detected change into a digital tension value. However, the configuration of the sensor units 111 may not be limited to the above description, and they may be connected directly to the first connection strings 101 and 102 one by one. In this case, the first connection strings 101 and 102 may be formed of an elastic material such as rubber.

The tension change analysis unit 120 analyzes the change of tension detected by the detection unit 110 to determine position of an input key on the keyboard corresponding to the movement of a finger. The tension change analysis unit 120 uses pieces of information stored in the tension storage measurement information storage unit 125 to determine the position of the input key of the keyboard. The tension measurement information storage unit 125 stores threshold values of each row of the keyboard which are previously set for each user based on a change of tension occurring on key input from the user, and a tension change information table with respect to tension between the first connection strings 101 and 102 and the wearing units 1 through 4 excluding the wearing unit to be worn on the thumb. In addition, the tension measurement information storage unit 125 may store standard threshold values set for individual rows of a keyboard. In this case, the keyboard may be a QWERTY keyboard, but the keyboard may be another type of keyboard according to settings. In case of a QWERTY keyboard, the threshold values include a first threshold value used for detecting key input in the center row including a key of “A,” a second threshold value used for detecting key input in an upper row including a key of “Q” and a lower row including a key of “Z,” and a third threshold value used for detecting key input in the remaining rows including keys of numbers and symbols. In the example, the third threshold value is greater than any other threshold values, and the first threshold value is the smallest. As such, by use of the set threshold values for each row of the keyboard, it can be determined whether the finger movement is related to key input or not, thereby preventing malfunction of the keyboard. The tension change information table stored in the tension measurement information storage unit 120 may be represented as Table 1 shown below.

TABLE 1

| | | Middle | | |
|---|---|---|---|---|
| | Index finger | finger | Ring finger | Little finger |
| Toward | 2/3/4 | | | |
| thumb | Upper/Lower | | | |
| Upward | 2/3/4 Lower | 2 Upper, 3/4 | 3 Upper, 4 | 4 Upper |
| | | Lower | Lower | |
| Downward | 2/3/4 Upper | 2 Lower, 3/4 | 3 Lower, 4 | 4 Lower |
| | | Upper | Upper | |
| Outward | | | | 4 Upper/Lower |

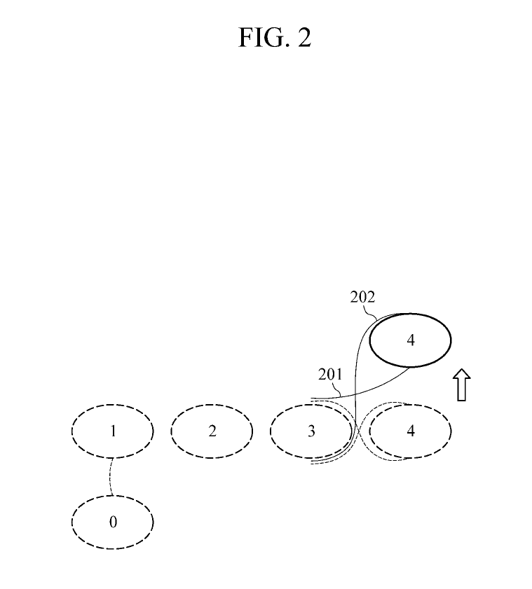

As shown in Table 1, the tension change information table shows a change of tension for the first connection strings 101 and 102 and fingers excluding the thumb according to the upward, downward, left, and right movement of the fingers. In the case of the thumb, since the thumb moves only in left and right directions without moving upward and downward, the wearing unit 0 to be worn on the thumb is connected by only one first connection string 102, and thus only the increase of tension occurs. In Table 2, the number corresponds to the wearing unit number and upper and lower means that tension of first connection string connected to the upper or lower side of wearing unit is increased. As shown in Table 1, as an index finger moves toward the thumb, the tension on the both first connection strings 101 and 102 connected to the wearing units 2, 3, and 4 which are respectively worn on a middle finger, a ring finger, and a little finger are increased. More specifically, the tension change information shown in Table 1 according to the finger movements will be described in detail with reference to FIGS. 2 through 4.

FIG. 2 illustrates an example of a change of tension according to upward movement of a right little finger.

As shown in the example illustrated in FIG. 2, a user may move his/her little finger upward while wearing the wearing unit 4 for key input to a keyboard. In this case, as the little finger is moved upward, among two first connection strings 201 and 202 connected to the wearing unit 4 worn on the little finger, a tension of the upper-side first connection string 202 is increased. On the other hand, a tension of the lower-side first connection string 201 is not significantly increased in comparison with the first connection string 202. That is, as shown in Table 1, it is noted that a tension of the first connection string 202 connected to an upper side of the wearing unit 4 worn on the little finger is increased according to the upward movement of the little finger.

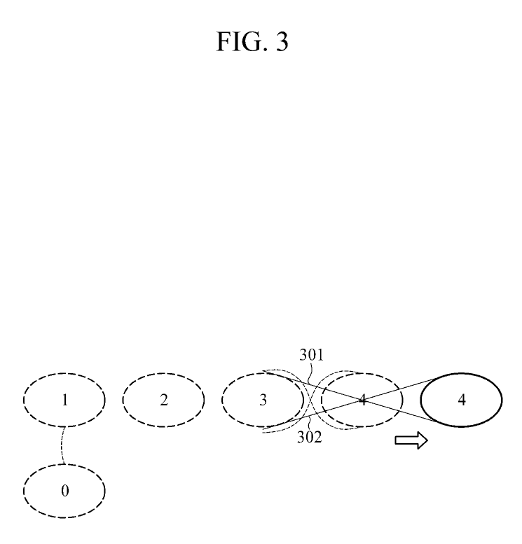

FIG. 3 illustrates an example of a change of tension according to a horizontal movement of a right little finger.

As shown in the example illustrated in FIG. 3, the user may move his/her little finger to the right while wearing a wearing unit 4 for key input to a keyboard. In this case, as the little finger is moved to the right, lengths of two first connection strings 301 and 302 connected to the wearing unit 4 worn on the little finger increase equally. That is, as shown in Table 1, it is noted that as the little finger is moved horizontally, the tensions of the first connection string 301 connected to an upper side of the wearing unit 4 and the first connection string 302 connected to a lower side of the wearing unit 4 increase equally.

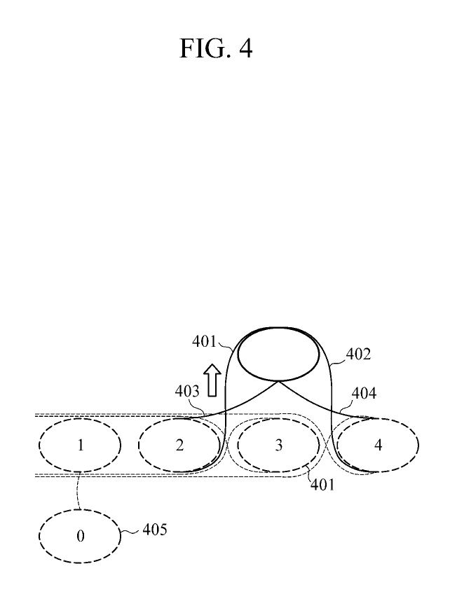

FIG. 4 illustrates an example of a change of tension according to upward movement of a right ring finger.

As shown in the example illustrated in FIG. 4, the user may move his/her right ring finger upward for key input to a keyboard while wearing a wearing unit 3 on the right ring finger. According to the upward movement of the ring finger, a first connection string 401 connected to an upper side of the wearing unit 3 worn on the ring finger and a first connection string 402 connected to a lower side of a wearing unit 4 worn on a little finger increase equally in tensions. On the other hand, a first connection string 403 connected to a lower side of the wearing unit 3 worn on the ring finger and a first connection string 404 connected to an upper side of the wearing unit 4 worn on the little finger do not increase in tensions. That is, as shown in Table 1, it is noted that as the ring finger is moved upward, the tensions of the first connection string 401 connected to the upper side of the wearing unit 3 worn on the ring finger and the first connection string 402 connected to the lower side of the wearing unit 4 worn on the little finger are increased.

As such, the tension measurement information storage unit 125 stores the threshold values for the respective rows of the keyboard, and the tension change information table regarding the changes of tension of the first connection strings 101 and 102 (see FIG. 1) according to the movements of the fingers excluding the thumb. Thus, the tension change analysis unit 120 uses the threshold values for the respective rows of the keyboard and the tension change information table which are stored in the tension measurement information storage unit 125 to determine position of an input key on the keyboard. The tension change analysis unit 120 may include a keyboard row determination unit 121 and a key position information acquisition unit 123 to determine the position of a key on the keyboard corresponding to the finger movement.

In response to receiving tension change information which is converted to digital tension value from the respective sensor units 113, the keyboard row determination unit 121 compares the threshold values for the respective rows of the keyboard which are stored in the tension measurement information storage unit 125 to determine a row of the keyboard that is involved with the received tension change information. The keyboard row determination unit 121 may check whether threshold values for the respective rows of the keyboard which are set for each user are stored in the tension measurement information storage unit 125 based on the tension change that occurs during the key input to the keyboard. When the check result indicates that the threshold values for the respective rows of the keyboard are stored, the keyboard row determination unit 121 compares digital tension values involved with the tension change information and the stored threshold values to determine a row of the keyboard. If the threshold values for the respective rows are not stored for individual user, the keyboard row determination unit 121 uses standard threshold values previously set for the respective rows of the keyboard to determine a row of the keyboard.

In response to receiving the digital tension value from the respective sensor units 113 that have performed a analog-to-digital conversion process on the tension, the keyboard row determination unit 121 may use the threshold values stored in the tension measurement information storage unit 125 to determine a keyboard row corresponding to the received digital tension values. First, the keyboard row determination unit 121 may check whether the received digital tension value is greater than the third threshold value. If the check result indicates that the received signal value is greater than or equal to the third threshold value, the keyboard row determination unit 121 may determine one of keyboard rows corresponding to numbers/symbols. If the check result indicates that the received digital tension value is smaller than the third threshold value, the keyboard row determination unit 121 checks whether the received digital tension value is greater than or equal to the second threshold value. If the check result indicates that the received digital tension value is greater than or equal to the second threshold value, the keyboard row determination unit 121 determines one of keyboard rows including a “Q” key or a “Z” key. If the received digital tension value is smaller than the second threshold value, the keyboard row determination unit 121 checks whether the received digital tension value is greater than or equal to the first threshold value. If the received digital tension value is greater than or equal to the first threshold value, the keyboard row determination unit 121 determines a keyboard row including an “A” key. If the received digital tension value is smaller than the first threshold value, the keyboard row determination unit 121 determines that the user's finger movement is not involved with the key input to the keyboard.

Once the keyboard row determination unit 121 determines the keyboard row, the tension change analysis unit 120 obtains position of a key corresponding to the user's finger movement from the key position information acquisition unit 123. The key position information acquisition unit 123 determines position of the key related to the tension, which is converted into the digital tension value, with reference to the tension change information table stored in the tension measurement information storage unit 125. In the example, when the keyboard row determination unit 121 determines that the user's finger movement involves the “A” row, the key position information acquisition unit 123 determines directions of a finger and an input key indicated by the finger with reference to the tension change information table stored in the tension measurement information storage unit 125. As the result, the key position information acquisition unit 123 can obtain the input key belonging to the “A” row of the keyboard.

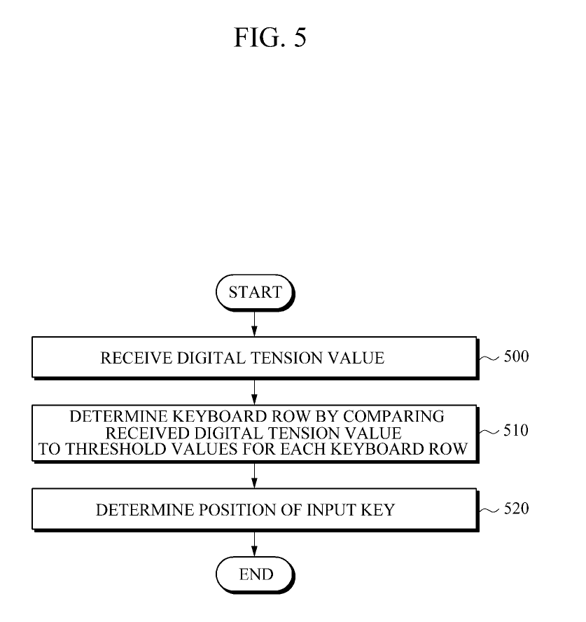

Hereinafter, an example of a method of acquiring position of an input key by analyzing tension change of a first connection string fixed to a wearing unit worn on a finger according to the movement of the finger will be described with reference to FIG. 5.

FIG. 5 illustrates a flowchart of an example of a method of acquiring position information of an input key.

As shown in the example illustrated in FIG. 5, a tension change analysis apparatus receives an electrical signal involved with a change of tension on a first connection strings from a detection unit which is connected to the first connection string at 500. The first connection string is attached or fixed on a fixation unit of a wearing unit in a shape of a ring or thimble, and connects the fixation unit to an adjacent fixation unit. For example, a wearing unit worn on the thumb is connected to the detection unit by a single first connection string attached to the fixation unit of the wearing unit. Then, wearing units for the rest of the fingers are connected to the detection unit by two first connection strings, which are attached to the fixation units of each wearing unit and pass through the fixation unit of an adjacent wearing unit close to the detection unit. The first connection strings may be inserted into a string guide unit to be connected to the detection unit. The detection unit may include sensors for the respective first connection strings, and each sensor may detect a tension change according to the movement of a finger wearing the wearing unit to which the first connection string is attached. The sensors may convert the tension change of the respective first connection strings into an digital tension value using second connection strings. The second connection strings may be formed of a high elastic material such as rubber. However, the sensors may be directly connected to the respective first connection strings, and in this case, the first connection strings may be formed of a high elastic material such as rubber.

In response to receiving the digital tension value involved with the tension change from the respective sensors, the tension change analysis apparatus compares the received electrical signals and threshold values for each keyboard row which are stored in a tension measurement information storage unit to determine a keyboard row related to received tension change information at 510. The threshold values for the respective keyboard rows stored in the tension measurement information storage unit may be set according to each user based on a change of tension occurring upon key input from the user, or be standard threshold values previously set. In this case, the keyboard may be a QWERTY keyboard, but may be a different type of keyboard according to set conditions. In the case of a QWERTY keyboard, the threshold values include a first threshold value used for detecting key input in the center row including a key of “A,” a second threshold value used for detecting key input in a upper row including a key of “Q” and a lower row including a key of “Z,” and a third threshold value used for detecting key input in the remaining rows including keys of numbers and symbols. Then, the third threshold value is larger than any other threshold values, and the first threshold value is the smallest. As such, by use of the set threshold values for each row of the keyboard, it can be determined whether the user's finger movement is related to key input or not, thereby preventing malfunction of the keyboard. Accordingly, when the electrical signals are converted according to the tension changes from the respective sensors, the tension change analysis apparatus compares the received electrical signals and the threshold values for the respective keyboard rows stored in the tension measurement information storage unit to determine the keyboard row related to the tension change information. The method of the determining the keyboard row by the tension change analysis apparatus will be described in detail later.

When the keyboard row is determined, the tension change analysis apparatus determines position of the input key related to the tension change information converted to the digital tension value with reference to the tension change information table stored in the tension measurement information storage unit with respect to the first connection strings connected to the fingers excluding the thumb at 520. The tension change information table is described with reference to Table 1 above, and thus the detailed description of the table will not be reiterated. For example, when it is determined that the user's finger movement corresponds to the “A” keyboard row, the tension change analysis apparatus determines a corresponding finger and a direction of the input key indicated by the corresponding finger with reference to the tension change information table as Table 1 described above. Thus, the tension change analysis apparatus determines the position of the input key belonging to the “A” keyboard row.

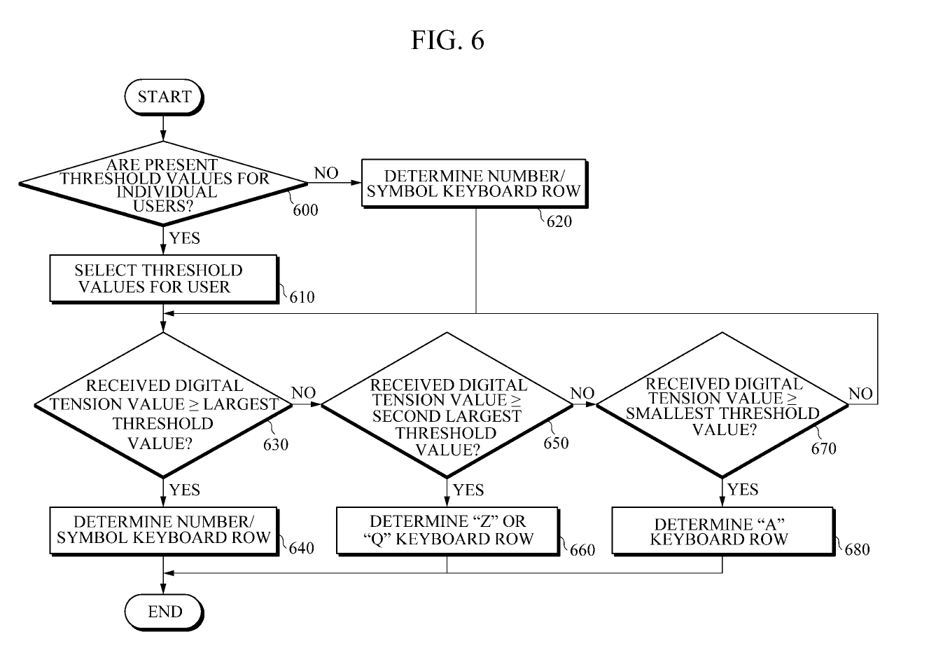

Hereinafter, an example of a method of determining a keyboard row related to tension change information by the above tension change analysis apparatus will be described in detail with reference to FIG. 6.

FIG. 6 illustrates a flowchart of an example of a method of determining a keyboard row related to tension change information.

In response to receiving digital tension value converted according to changes of tension on first connection strings from sensors, it is checked whether threshold values for keyboard rows which are set according to each user are stored in a tension measurement information storage unit at 600. If it is determined that the threshold values are present in the tension measurement information storage unit, a tension change analysis apparatus selects the threshold values for each keyboard row set according to each user at 610. Otherwise, the tension change analysis apparatus selects previously set standard threshold values at 620. That is, in response to receiving the threshold values set according to each user, or the standard threshold values, the tension change analysis apparatus uses a third threshold value among the stored threshold values, and compares the third threshold value to a value of the received digital tension value. The tension change analysis apparatus checks whether the received digital tension value is greater than or equal to the third threshold value, and if the received digital tension value is determined to be greater than or equal to the third threshold value at 630, a keyboard row including numbers and symbols is determined to be related to the received electrical signal at 640.

Meanwhile, if the received digital tension value is smaller than the third threshold value, the tension change analysis apparatus checks whether the received signal value is greater than or equal to the second threshold value at 650. If the received signal value is determined to be greater than or equal to the second threshold value, the tension change analysis apparatus determines a keyboard row including a key of “Q” or a keyboard row including a key of “Z” to be related to the received digital tension value at 660. If the received digital tension value is smaller than the second threshold value, the tension change analysis apparatus checks whether the received digital tension value is greater than or equal to the first threshold value at 670. If the received digital tension value is greater than or equal to the first threshold value, the tension change analysis apparatus determines that the received signal is related to a keyboard row including a key of “A” at 680. If the received digital tension value is smaller than the first threshold value, the tension change analysis apparatus determines that the user's finger movement is not involved with a key input, and performs analysis on an electrical signal received from another sensor to determine a corresponding keyboard row. As such, in response to determining the keyboard row, the tension change analysis apparatus determines a finger and a direction of an input key indicated by the finger with reference to the tension change information table stored in the tension measurement information storage unit. Hence, the tension change analysis apparatus can obtain position of the input key belonging to the determined keyboard row.

As described above, the portable character input apparatus can be prevented from being damaged by an external force since it is formed of flexible material such as rubber. Also, when the portable character input apparatus is not in use, the wearing units may be used as an accessory of a mobile terminal. Accordingly, the portable character input apparatus is easy to carry. In addition, a user can input data with the same finger movements as on a general keyboard without restriction on input space because the portable character input apparatus detects relative positions of the user's fingers and operates according to the detection result.

A number of examples have been described above. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A portable character input apparatus comprising:
a plurality of wearing units, each configured to be worn on or attached to a finger;
at least one or more first connection strings, each configured to be attached to the wearing units;
a detecting unit configured to detect a change of tension on the first connecting string according to movement of the finger wearing the wearing unit; and
a tension change analysis unit configured to analyze the change of tension detected by the detection unit to determine position of an input key that corresponds to the movement of the finger.

2. The portable character input apparatus of claim 1, wherein each of the wearing units is further configured to be ring- or thimble-shaped and formed of high elastic material such as rubber, and comprise a string guide unit for fixing the first connection string.

3. The portable character input apparatus of claim 1, wherein the detecting unit is further configured to comprise:
a second connection string configured to be formed of elastic material and connected to the first connection string, and
a sensor unit configured to detect the change of tension on the first connection string through the second connection string and convert the detected change of tension into an digital tension value.

4. The portable character input apparatus of claim 3, wherein, among the plurality of wearing units, a wearing unit worn on the thumb is configured to be connected to a single first connection string, and each of the rest of the wearing units is connected to two first connection strings crossing each other in an X shape.

5. The portable character input apparatus of claim 3, further comprising:
a tension measurement information storage unit configured to store threshold values for keyboard rows of a keyboard which are set according to each user based on a change of tension occurring upon key input from each user, and a tension change information table with respect to changes of tension on the first connection string according to movements of the fingers excluding the thumb.

6. The portable character input apparatus of claim 5, wherein the tension change analysis unit is further configured to comprise:
a keyboard row determination unit configured to, in response to receiving tension change information converted into an electrical signal from the sensor unit, compare a value of the received digital tension value and the threshold values for identifying the keyboard rows which are stored in the tension measurement information storage unit to determine a keyboard row related to the received tension change information, and
a key position information acquisition unit configured to determine position of an input key belonging to the keyboard row determined by the keyboard row determination unit with reference to the tension change information table stored in the tension measurement information storage unit.

7. The portable character input apparatus of claim 5, wherein the tension measurement information storage unit is configured to store standard threshold values for the respective keyboard rows, and the keyboard row determination unit is further configured to determine a keyboard row using the standard threshold values when the threshold values for the respective keyboard rows which are set according to each user are not stored in the tension measurement information storage unit.

8. A method of determining position of an input key on a keyboard by analyzing a change of tension on a first connection string attached to a wearing unit worn on a finger of a user according to movement of the finger, the method comprising:
receiving an digital tension value converted from tension change information about the change of tension on the first connection string from a sensor unit connected to the first connection string;
in response to receiving the tension change information converted into the digital tension value, determining a keyboard row related to the received tension change information by comparing a value of the received electrical signal and threshold values for keyboard rows of the keyboard which are stored in a tension measurement information storage unit; and
in response to determining the keyboard row, acquiring position information of an input key belonging to the determined keyboard row and related to the tension change information converted into the digital tension value with reference to a tension change information table with respect to changes of tension on the first connection string according to movements of the fingers excluding the thumb.

9. The method of claim 8, wherein the threshold values stored in the tension measurement storage unit are threshold values set according to each user based on a change of tension occurring upon a key input from the user, or previously set standard threshold values.

10. The method of claim 9, wherein the determining of the keyboard row comprises
checking whether the tension measurement information storage unit stores the threshold values for the respective keyboard rows of the keyboard which are set according to each user, and
if the threshold values are not stored, determining the keyboard row using the previously set standard threshold values.

11. The method of clam 8, wherein the determining of the keyboard row comprises checking whether the value of the received digital tension value is greater than or equal to the largest threshold value among the stored threshold values, and if the value is greater than or equal to the largest threshold value, determining a keyboard row including numbers/symbols.

12. The method of claim 11, wherein the determining of the keyboard row comprises, if the value of the received digital tension value is smaller than the largest threshold value, checking whether the value is greater than or equal to the second largest threshold value among the stored threshold values, and if the value is greater than or equal to the second largest threshold value, determining a keyboard row including a key of “Q” or a keyboard row including a key of “Z.”

13. The method of claim 12, wherein the determining of the keyboard row comprises,
if the value of the received digital tension value is smaller than the second largest threshold value, checking whether the value is greater than or equal to the smallest threshold value among the stored threshold values, and
if the value is greater than or equal to the smallest threshold value, determining a keyboard row including a key of “A,” and otherwise, determining that the value is irrelevant to the determination of the keyboard row.
